(19) United States
(12) Patent Application Publication
(10) Pub. No.: US 2025/0354950 A1
(43) Pub. Date: Nov. 20, 2025

(54) MEASURING INSTRUMENT AND MEASURING METHOD

(71) Applicant: Tokyo Electron Limited, Tokyo (JP)

(72) Inventors: Kimihiro YOKOYAMA, Miyagi (JP); Hikaru FUJIWARA, Miyagi (JP)

(73) Assignee: Tokyo Electron Limited, Tokyo (JP)

(21) Appl. No.: 19/284,690

(22) Filed: Jul. 30, 2025

Related U.S. Application Data
(63) Continuation of application No. PCT/JP2024/002875, filed on Jan. 30, 2024.

(30) Foreign Application Priority Data
Feb. 6, 2023 (JP) 2023-016214

(51) Int. Cl. G01N 27/22

(52) U.S. Cl. CPC G01N 27/228

(57) ABSTRACT

A measuring instrument according to an exemplary embodiment includes a base substrate having a disk shape, a plurality of first sensors arranged along a peripheral edge of the base substrate, a circuit substrate fixed on the base substrate, and a cover fixed to the circuit substrate or the base substrate to cover the top of the circuit substrate. The plurality of first sensors measure capacitance between the plurality of first sensors and a first object disposed beside the base substrate. An expansion rate of the base substrate is smaller than an expansion rate of the circuit substrate. The expansion rate of the circuit substrate is smaller than an expansion rate of the cover.

### CROSS-REFERENCE TO RELATED APPLICATIONS

This application is a bypass continuation application of international application No. PCT/JP2024/002875 having an international filing date of Jan. 30, 2024 and designating the United States, the international application being based upon and claiming the benefit of priority from Japanese Patent Application No. 2023-016214, filed on Feb. 6, 2023, the entire contents of each are incorporated herein by reference.

### TECHNICAL FIELD

Exemplary embodiments of the present disclosure relate to a measuring instrument and a measuring method.

### BACKGROUND

JP2005-521926A discloses a substrate-shaped sensor for performing calibration of a semiconductor processing system. The substrate-shaped sensor includes a substrate-shaped housing, a power supply unit for supplying power to the sensor, an imaging apparatus for capturing an image, a processor for processing the image, and a communication module for transmitting data to an external apparatus.

### CITATION LIST

### Patent Documents

Patent Literature 1: Japanese Patent Application Publication No. 2005-521926

### SUMMARY

The present disclosure provides a technique for measuring capacitance with high accuracy in a temperature environment similar to a temperature environment in which process treatment is performed.

In one exemplary embodiment, a measuring instrument is provided. The measuring instrument includes a base substrate having a disk shape. The measuring instrument includes a plurality of first sensors arranged along a peripheral edge of the base substrate. The plurality of first sensors measure capacitance between the plurality of first sensors and a first object disposed beside the base substrate. The measuring instrument includes a circuit substrate fixed on the base substrate. The circuit substrate includes an arithmetic unit that controls the plurality of first sensors. The measuring instrument includes a cover fixed to the circuit substrate or the base substrate to cover a top of the circuit substrate. An expansion rate of the base substrate is smaller than an expansion rate of the circuit substrate. The expansion rate of the circuit substrate is smaller than an expansion rate of the cover.

According to the measuring instrument of the exemplary embodiment, it is possible to measure the capacitance with high accuracy in a temperature environment similar to a temperature environment in which process treatment is performed.

### BRIEF DESCRIPTION OF DRAWINGS

FIG. 1 is a view illustrating a processing system.

FIG. 2 is a perspective view illustrating an aligner.

FIG. 3 is a view illustrating an example of a plasma processing apparatus.

FIG. 4 is a plan view illustrating an exemplary measuring instrument as viewed from an upper surface side.

FIG. 5 is a plan view illustrating the exemplary measuring instrument as viewed from a lower surface side.

FIG. 6 is a perspective view illustrating an example of a first sensor in the measuring instrument.

FIG. 7 is a cross-sectional view of the first sensor in the measuring instrument.

FIG. 8 is an enlarged view illustrating an example of a second sensor in the measuring instrument.

FIG. 9 is a view illustrating an example of a configuration of a circuit substrate in the measuring instrument.

FIG. 10 is a cross-sectional view taken along the line X-X in FIG. 4.

FIG. 11 is a flowchart illustrating an example of a measuring method using the measuring instrument.

### DETAILED DESCRIPTION

Hereinafter, various exemplary embodiments will be described.

In one exemplary embodiment, a measuring instrument is provided. The measuring instrument includes a base substrate having a disk shape. The measuring instrument includes a plurality of first sensors arranged along a peripheral edge of the base substrate. The plurality of first sensors measure capacitance between the plurality of first sensors and a first object disposed beside the base substrate. The measuring instrument includes a circuit substrate fixed on the base substrate. The circuit substrate includes an arithmetic unit that controls the plurality of first sensors. The measuring instrument includes a cover fixed to the circuit substrate or the base substrate to cover a top of the circuit substrate. An expansion rate of the base substrate is smaller than an expansion rate of the circuit substrate. The expansion rate of the circuit substrate is smaller than an expansion rate of the cover.

In the above-described measuring instrument, the circuit substrate is fixed on the base substrate having a disk shape, and the cover that covers the circuit substrate is fixed to the base substrate or the circuit substrate. In the above-described measuring instrument, the base substrate, the circuit substrate, and the cover are configured to be sequentially stacked from the lower side to the upper side. The expansion rate of the base substrate is the smallest, followed by the circuit substrate, and then the cover, in that order. In this configuration, when exposed to a high-temperature environment similar to that in which a process treatment is performed, the deformation amount (expansion amount) of the cover is the highest, followed by the circuit substrate and then the base substrate, in that order. Therefore, the measuring instrument is deformed in a direction in which the peripheral edge is bent downward such that the cover having a large deformation amount is pulled by the base substrate having a small deformation amount. In this case, the variation in the height position of the peripheral edge of the measuring instrument is suppressed in a state where the measuring instrument is placed at a predetermined position. That is, even in a high-temperature environment, the distance to the first object disposed to the side of the measuring instrument is unlikely to vary. The capacitance acquired by the first sensor depends on the distance between the first sensor and the first object. Therefore, it is possible to measure the capacitance with high accuracy even in a high-temperature environment.

In one exemplary embodiment, the base substrate may be made of any one of materials of monocrystalline silicon, carbon fiber reinforced plastic, silicon carbide, and alumina. The circuit substrate may be made of any one of materials of materials of glass epoxy and polyimide resin. The cover may be made of any one of materials of polyether ether ketone resin, polytetrafluoroethylene resin, polyphenylene sulfide resin, and epoxy resin.

In one exemplary embodiment, the cover may include a first cover and a second cover which are separately formed from each other. The first cover and the second cover may be fixed to the circuit substrate or the base substrate by different fastening members. With this configuration, the deformation amount of the cover can be reduced compared to the case where the cover is integrated.

In one exemplary embodiment, the second cover may extend along the radial direction of the base substrate spaced apart from the peripheral edge of the first cover. In this configuration, since the deformation of the measuring instrument is along the radial direction, for example, the distortion along the circumferential direction can be reduced.

In one exemplary embodiment, the first cover may be disposed at the center of the base substrate. The plurality of second covers may be disposed radially around the first cover. In this configuration, deviation of deformation in the circumferential direction is suppressed.

In one exemplary embodiment, the circuit substrate may be fixed on the base substrate by an elastic adhesive layer. The elastic adhesive layer can mitigate the amount of change in the circuit substrate on the base substrate.

In one exemplary embodiment, the measuring instrument may further include a plurality of second sensors arranged along a peripheral edge of the base substrate. The plurality of second sensors measure capacitance between the plurality of second sensors and a second object disposed below the base substrate. The height positions of the lower surfaces of the plurality of second sensors may be offset from the height position of the lower surface of the base substrate toward the upper surface of the base substrate. In this configuration, the base substrate is not supported by the plurality of second sensors.

In one exemplary embodiment, a measuring method is provided for acquiring, by a measuring instrument, a measurement value representing capacitance in a chamber of a processing system for executing a process treatment. The measuring method includes controlling a temperature environment in the chamber. The measuring method includes transporting the measuring instrument by a transport device onto an electrostatic chuck in a chamber in which a temperature environment is controlled. The measuring method includes attracting the measuring instrument transported onto the electrostatic chuck to the electrostatic chuck. The measuring method includes acquiring a measurement value representing the capacitance between the measuring instrument and the edge ring that surrounds the measuring instrument by the measuring instrument attracted to the electrostatic chuck. In this method, the measuring instrument is attracted to the electrostatic chuck, which suppresses distortion of the measuring instrument.

Hereinafter, various exemplary embodiments will be described in detail with reference to the drawings. Further, like reference numerals will be given to like or corresponding parts throughout the drawings.

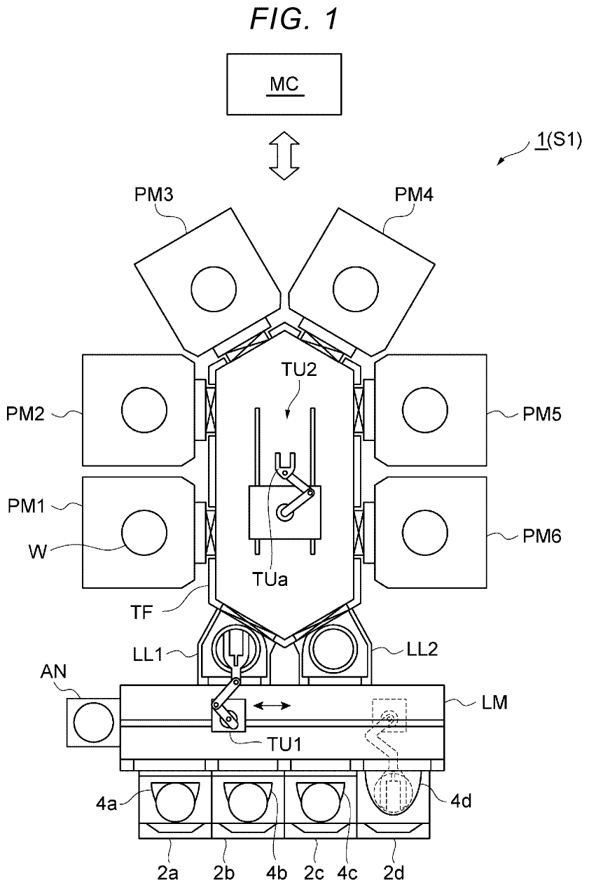

First, a processing system that includes a processing apparatus for processing a workpiece and a transport device for transporting the workpiece to the processing apparatus will be described. FIG. 1 is a diagram illustrating the processing system. A processing system 1 has a function as a semiconductor manufacturing apparatus S1. The processing system 1 is provided with stages 2a to 2d, containers 4a to 4d, a loader module LM, an aligner AN, load-lock modules LL1 and LL2, process modules PM1 to PM6, a transfer module TF, and a controller MC. The number of stages 2a to 2d, the number of containers 4a to 4d, the number of load-lock modules LL1 and LL2, and the number of process modules PM1 to PM6 are not limited, and may be any number of one or more.

The stages 2a to 2d are arranged along one side of a loader module LM. The containers 4a to 4d are placed on the stages 2a to 2d, respectively. Each of the containers 4a to 4d is, e.g., a container referred to as a Front Opening Unified Pod (FOUP). Each of the containers 4a to 4d may be configured to accommodate a workpiece W. The workpiece W has an approximate disc shape like a wafer.

The loader module LM has a chamber wall defining in an inside thereof a transport space in an atmospheric pressure state. A transport device TU1 is provided in the transport space. The transport device TU1 is, for example, an articulated robot and is controlled by the controller MC. The transport device TU1 is configured to transport the workpiece W between the containers 4a to 4d and the aligner AN, between the aligner AN and the load-lock modules LL1 to LL2, and between the load-lock modules LL1 to LL2 and the containers 4a to 4d.

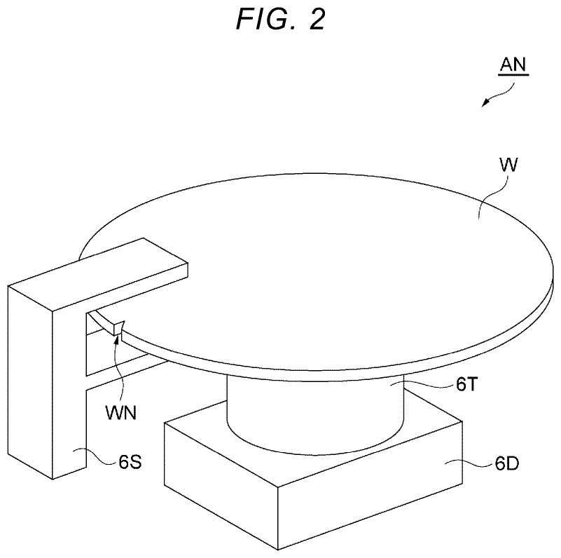

The aligner AN is connected to the loader module LM. The aligner AN is configured to adjust a position (calibrate a position) of the workpiece W. FIG. 2 is a perspective view illustrating the aligner. The aligner AN includes a support stand 6T, a driving device 6D, and a sensor 6S. The support stand 6T is a stand that can rotate around an axis extending in a vertical direction, and is configured to support the workpiece W thereon. The support stand 6T is rotated by the driving device 6D. The driving device 6D is controlled by the controller MC. When the support stand 6T is rotated by the power from the driving device 6D, the workpiece W placed on the support stand 6T is also rotated.

The sensor 6S is an optical sensor and detects an edge of the workpiece W while the workpiece W is rotated. The sensor 6S detects a misalignment amount of the angular position of a notch WN (or another marker) of the workpiece W with respect to a reference angular position, and a misalignment amount of the central position of the workpiece W with respect to the reference position from the detection result of the edge. The sensor 6S outputs the misalignment amount of the angular position of the notch WN and the misalignment amount of the central position of the workpiece W to the controller MC. The controller MC calculates a rotation amount of the support stand 6T for correcting the angular position of the notch WN to the reference angular position based on the misalignment amount of the angular position of the notch WN. The controller MC controls the driving device 6D to rotate the support stand 6T only by the rotation amount. As a result, the angular position of the notch WN can be corrected to the reference angular position. In addition, the controller MC controls the position of an end effector of the transport device TU1 when receiving the workpiece W from the aligner AN based on the misalignment amount of the central position of the workpiece W. As a result, the central position of the workpiece W coincides with the predetermined position on the end effector of the transport device TU1.

Referring back to FIG. 1, each of the load-lock module LL1 and the load-lock module LL2 is provided between the loader module LM and the transfer module TF. Each of the load-lock modules LL1 and LL2 provides a preliminary depressurization chamber.

The transfer module TF is connected to the load-lock module LL1 and the load-lock module LL2 in an airtight manner through a gate valve. The transfer module TF provides a decompression chamber capable of decompression. The decompression chamber is provided with a transport device TU2. The transport device TU2 is, for example, an articulated robot having a transport arm TUa and is controlled by the controller MC. The transport device TU2 is configured to transport the workpiece W between the load-lock modules LL1 to LL2 and the process modules PM1 to PM6, and between any two of the process modules PM1 to PM6.

The process modules PM1 to PM6 are connected to the transfer module TF in an airtight manner through gate valves. Each of the process modules PM1 to PM6 is a processing apparatus configured to perform dedicated processing such as plasma processing on the workpiece W.

A series of operations when the processing of the workpiece W is performed in the processing system 1 will be exemplified as follows. The transport device TU1 of the loader module LM takes out the workpiece W from any one of the containers 4a to 4d, and transports the workpiece W to the aligner AN. Next, the transport device TU1 takes out the workpiece W whose position is adjusted from the aligner AN, and transports the workpiece W to one load-lock module of the load-lock module LL1 and the load-lock module LL2. Next, the one load-lock module decompresses the pressure in the preliminary decompression chamber to a predetermined pressure. Next, the transport device TU2 of the transfer module TF takes out the workpiece W from the one load-lock module, and transports the workpiece W to any one of the process modules PM1 to PM6. One or more process modules of the process modules PM1 to PM6 process the workpiece W. The transport device TU2 transports the processed workpiece W from the process module to one load-lock module of the load-lock module LL1 and the load-lock module LL2. Next, the transport device TU1 transports the workpiece W from the one load-lock module into any one of the containers 4a to 4d.

The processing system 1 is provided with the controller MC as described above. The controller MC may be a computer including a processor, a storage device such as a memory, a display device, an input and output device, a communication device, and the like. A series of operations of the processing system 1 described above is realized by the control of each part of the processing system 1 by the controller MC according to a program stored in the storage device. The functionality of the elements disclosed herein may be implemented using circuitry or processing circuitry which includes general purpose processors, special purpose processors, integrated circuits, ASICs (“Application Specific Integrated Circuits”), FPGAS (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

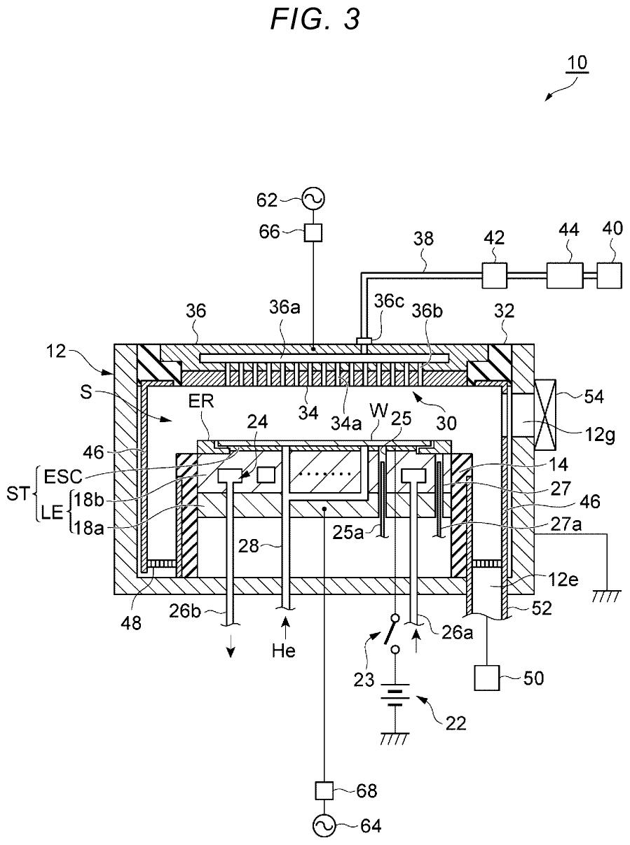

FIG. 3 is a view illustrating an example of the plasma processing apparatus which may be adopted as any one of the process modules PM1 to PM6. A plasma processing apparatus 10 illustrated in FIG. 3 is a capacitively-coupled plasma etching apparatus. The plasma processing apparatus 10 is provided with a substantially cylindrical chamber main body 12. The chamber main body 12 is made of, for example, aluminum. An inner wall surface of the chamber main body 12 may be anodized. The chamber main body 12 is grounded for safety.

A substantially cylindrical support 14 is provided on a bottom portion of the chamber main body 12. The support 14 is made of, for example, an insulating material. The support 14 is provided in the chamber main body 12. The support 14 extends upward from a bottom of the chamber main body 12. In addition, a stage ST is provided in the chamber S provided by the chamber main body 12. The stage ST is supported by the support 14.

The stage ST has a lower electrode LE and an electrostatic chuck ESC. The lower electrode LE includes a first plate 18a and a second plate 18b. The first plate 18a and the second plate 18b are made of, for example, metal such as aluminum. The first plate 18a and the second plate 18b have a substantially disc shape. The second plate 18b is provided on the first plate 18a. The second plate 18b is electrically connected to the first plate 18a.

The electrostatic chuck ESC is provided on the second plate 18b. The electrostatic chuck ESC has a structure in which an electrode which is a conductive film is disposed between a pair of insulating layers or insulating sheets. The electrostatic chuck ESC has a substantially disc shape. A DC power source 22 is electrically connected to the electrode of the electrostatic chuck ESC through a switch 23. The electrostatic chuck ESC adsorbs the workpiece W by an electrostatic force such as a Coulomb force generated by a DC voltage from the DC power source 22. As a result, the electrostatic chuck ESC can hold the workpiece W.

An edge ring ER is placed on the peripheral edge portion of the second plate 18b. This edge ring ER is formed, for example, in an annular shape. When the edge ring ER is placed on the second plate 18b, the edge ring ER surrounds the electrostatic chuck ESC in a plan view. That is, the electrostatic chuck ESC is located within the region surrounded by the edge ring ER. When the workpiece W is transported onto the electrostatic chuck ESC, the edge ring ER surrounds the edge of the workpiece W. That is, the workpiece W is located within the region surrounded by the edge ring ER. Similarly, when a measuring instrument 100 described below is transported onto the electrostatic chuck ESC, the edge ring ER surrounds the edge of the measuring instrument 100. That is, the measuring instrument 100 is located within the region surrounded by the edge ring ER.

A coolant passage 24 is provided in the second plate 18b. The coolant passage 24 configures a temperature control mechanism. A coolant is supplied from a chiller unit provided outside the chamber main body 12 to the coolant passage 24 through a pipe 26a. The coolant supplied to the coolant passage 24 is returned to the chiller unit through the pipe 26b. In this manner, the coolant is circulated between the coolant passage 24 and the chiller unit. By controlling the temperature of the coolant, the temperature of the workpiece W supported by the electrostatic chuck ESC is controlled.

A plurality (for example, three) of through-holes 25 penetrating the stage ST are formed in the stage ST. The through-holes 25 are formed inside the electrostatic chuck ESC in a plan view. A lift pin 25a is inserted into each of the through-holes 25. FIG. 3 illustrates one through-hole 25 into which one lift pin 25a is inserted. The lift pin 25a is vertically movable in the through-hole 25. As the lift pin 25a rises, the workpiece W supported on the electrostatic chuck ESC rises.

In the stage ST, a plurality (for example, three) of through-holes 27 penetrating the stage ST (lower electrode LE) are formed at positions outside the electrostatic chuck ESC in a plan view. The lift pin 27a is inserted into each of the through-holes 27. FIG. 3 illustrates one through-hole 27 into which one lift pin 27a is inserted. The lift pin 27a is vertically movable in the through-hole 27. As the lift pin 27a rises, the edge ring ER supported on the second plate 18b rises.

In addition, the plasma processing apparatus 10 is provided with a gas supply line 28. The gas supply line 28 supplies a heat transfer gas from a heat transfer gas supply mechanism, for example, a He gas, to a space between the upper surface of the electrostatic chuck ESC and the rear surface of the workpiece W.

In addition, the plasma processing apparatus 10 is provided with an upper electrode 30. The upper electrode 30 is disposed above the stage ST so as to face the stage ST. The upper electrode 30 is supported on an upper portion of the chamber main body 12 via an insulating shielding member 32. The upper electrode 30 may include a top plate 34 and a support 36. The top plate 34 faces the chamber S. The top plate 34 is provided with a plurality of gas discharge holes 34a. The top plate 34 may be formed of silicon or quartz. Alternatively, the top plate 34 may be configured by forming a plasma-resistant film such as yttrium oxide on the surface of an aluminum base material.

The support 36 is a component that detachably supports the top plate 34. The support 36 may be formed of, for example, a conductive material such as aluminum. The support 36 may have a water-cooled structure. A gas diffusion chamber 36a is provided in the interior of the support 36. A plurality of gas flow holes 36b communicating with the gas discharge holes 34a extend downward from the gas diffusion chamber 36a. Further, a gas introduction port 36c for introducing a processing gas into the gas diffusion chamber 36a is formed in the support 36. A gas supply pipe 38 is connected to the gas introduction port 36c.

A gas source group 40 is connected to the gas supply pipe 38 through a valve group 42 and a flow rate controller group 44. The gas source group 40 includes a plurality of gas sources for a plurality of types of gases. The valve group 42 includes a plurality of valves, and the flow rate controller group 44 includes a plurality of flow rate controllers such as mass flow controllers. The plurality of gas sources of the gas source group 40 are connected to the gas supply pipe 38 through the corresponding valves of the valve group 42 and the corresponding flow rate controllers of the flow rate controller group 44, respectively.

In addition, in the plasma processing apparatus 10, a deposition shield 46 is detachably provided along the inner wall of the chamber main body 12. The deposition shield 46 is also provided on the outer periphery of the support 14. The deposition shield 46 is a component that prevents etching by-products (deposits) from adhering to the chamber main body 12. The deposition shield 46 may be configured by coating an aluminum material with ceramics such as yttrium oxide.

An exhaust plate 48 is provided on the bottom portion side of the chamber main body 12 and between the support 14 and the side wall of the chamber main body 12. The exhaust plate 48 may be configured, for example, by coating an aluminum material with ceramic such as yttrium oxide. The exhaust plate 48 is formed with a plurality of holes penetrating in the plate thickness direction. An exhaust port 12e is provided below the exhaust plate 48 and in the chamber main body 12. An exhaust device 50 is connected to the exhaust port 12e via an exhaust pipe 52. The exhaust device 50 includes a pressure adjusting valve, and a vacuum pump such as a turbo molecular pump. The exhaust device 50 can reduce the pressure in the space inside the chamber main body 12 to a desired vacuum level. In addition, a loading and unloading port 12g for the workpiece W is provided in the side wall of the chamber main body 12, and the loading and unloading port 12g can be opened and closed by the gate valve 54.

In addition, the plasma processing apparatus 10 is further provided with a first radio-frequency power supply 62 and a second radio-frequency power supply 64. The first radio-frequency power supply 62 is a power supply that generates a first radio-frequency for plasma generation. The first radio-frequency power supply 62 generates a radio-frequency having a frequency of, for example, 27 MHz to 100 MHz. The first radio-frequency power supply 62 is connected to the upper electrode 30 via a matcher 66. The matcher 66 includes a circuit for matching the output impedance of the first radio-frequency power supply 62 with the input impedance on a load side (upper electrode 30 side). The first radio-frequency power supply 62 may be connected to the lower electrode LE via the matcher 66.

The second radio-frequency power supply 64 is a power supply that generates a second radio-frequency for drawing ions to the workpiece W. The second radio-frequency power supply 64 generates a radio-frequency having a frequency in a range of, for example, 400 kHz to 13.56 MHz. The second radio-frequency power supply 64 is connected to the lower electrode LE through the matcher 68. The matcher 68 includes a circuit for matching the output impedance of the second radio-frequency power supply 64 with the input impedance of the load side (lower electrode LE side).

In the plasma processing apparatus 10, a gas from one or more gas sources selected from the plurality of gas sources is supplied into the chamber S. In addition, the pressure in the chamber S is set to a predetermined pressure by the exhaust device 50. Furthermore, the gas in the chamber S is excited by the first radio-frequency from the first radio-frequency power supply 62. As a result, plasma is generated. The workpiece W is processed by the generated active species. If necessary, the ions may be attracted into the workpiece W by the bias based on the second radio-frequency of the second radio-frequency power supply 64.

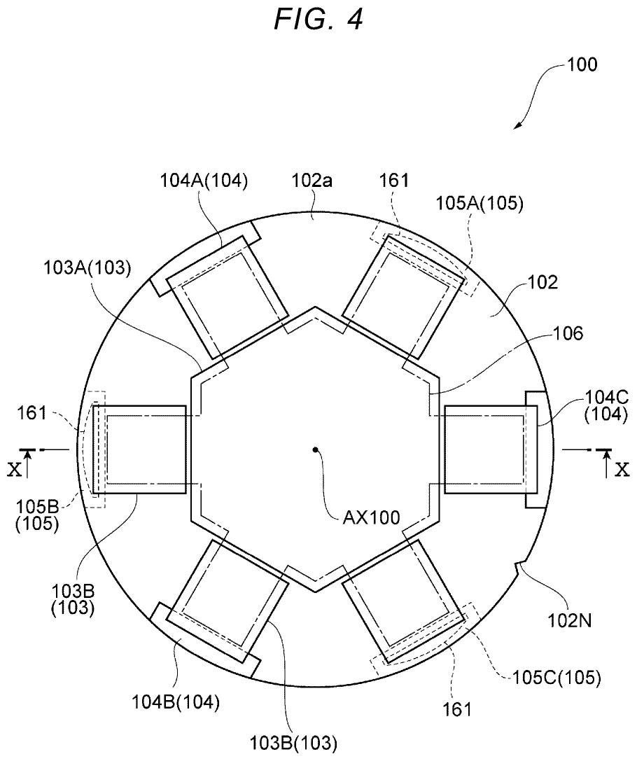

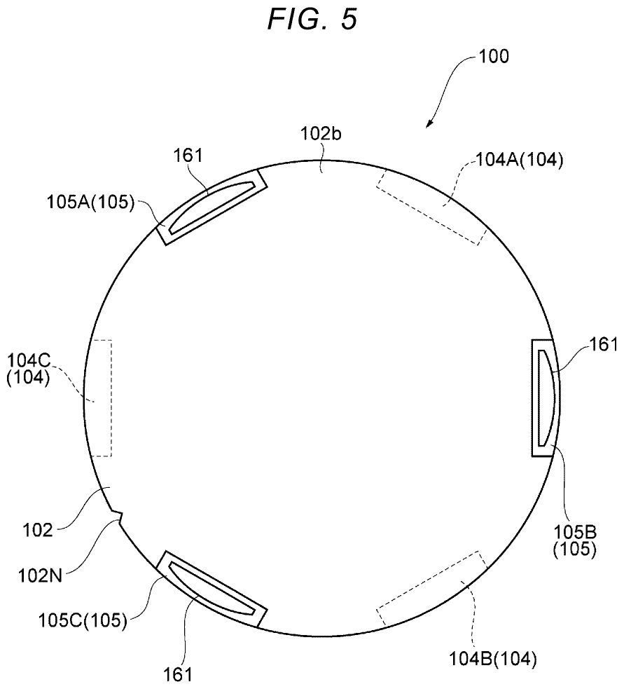

Next, the measuring instrument 100 will be described. FIG. 4 is a plan view illustrating the measuring instrument as viewed from an upper surface side. FIG. 5 is a plan view illustrating the measuring instrument as viewed from a lower surface side. The measuring instrument 100 includes a base substrate 102, first sensors 104 (104A to 104C), second sensors 105 (105A to 105C), a circuit substrate 106, and a cover 103.

The base substrate 102 has a shape similar to the shape of the workpiece W, that is, a substantially disc shape. A diameter of the base substrate 102 is the same as a diameter of the workpiece W, and is, for example, 300 mm. The shape and dimensions of the measuring instrument 100 are defined by the shape and dimensions of the base substrate 102. Therefore, the measuring instrument 100 has a shape similar to the shape of the workpiece W and has dimensions similar to the dimensions of the workpiece W. Further, a notch 102N (or another marker) is formed at an edge of the base substrate 102.

A plurality of first sensors 104A to 104C are sensors for measuring capacitance. The first sensors 104A to 104C are arranged at equal intervals in a circumferential direction along the edge of the base substrate 102, for example, over the entire circumference of the edge. Specifically, each of the plurality of first sensors 104A to 104C is arranged along the edge of an upper surface 102a of the base substrate 102. Front end surfaces of the first sensors 104A to 104C extend along a side surface of the base substrate 102. Therefore, the plurality of first sensors 104A to 104C can measure the capacitance between the plurality of first sensors and an object (first object) disposed beside the base substrate 102. For example, in a state where the measuring instrument 100 is placed on the electrostatic chuck ESC, the plurality of first sensors 104A to 104C can measure the capacitance between the measuring instrument 100 and the inner surface of the edge ring ER that surrounds the peripheral edge of the electrostatic chuck ESC.

A plurality of second sensors 105A to 105C are sensors for measuring capacitance. The second sensors 105A to 105C are arranged at equal intervals in the circumferential direction along the edge of the base substrate 102, for example, over the entire circumference of the edge. The second sensors 105A to 105C and the first sensors 104A to 104C are arranged alternately at 60° intervals in the circumferential direction. Each of the plurality of second sensors 105A to 105C is arranged along the edge of a lower surface 102b of the base substrate 102. Sensor electrodes 161 of the respective second sensors 105A to 105C extend along an extending direction of the lower surface 102b of the base substrate 102. Therefore, the plurality of second sensors 105A to 105C can measure the capacitance between the plurality of second sensors and an object (second object) disposed below the base substrate 102. For example, in a state where the measuring instrument 100 is placed on the electrostatic chuck ESC, the plurality of second sensors 105A to 105C can measure the capacitance between the measuring instrument 100 and the electrostatic chuck ESC. In the following description, the first sensors 104A to 104C and the second sensors 105A to 105C may be collectively referred to as capacitance sensors.

The circuit substrate 106 includes an arithmetic unit that controls the electrostatic capacitance sensors as described later. The circuit substrate 106 is disposed on the upper surface 102a of the base substrate 102. The circuit substrate 106 in the illustrated example extends in the center of the upper surface 102a of the base substrate 102 and extends from the center along the radial direction of the base substrate 102 toward the first sensor 104 or the second sensor 105 disposed at the peripheral edge.

The cover 103 covers the circuit substrate 106. That is, when the measuring instrument 100 is viewed from above, the circuit substrate 106 may be covered with the cover 103. In one exemplary embodiment, the cover 103 may include a first cover 103A and a second cover 103B which are separately formed from each other. The first cover 103A covers a portion of the circuit substrate 106 extending to the center of the upper surface 102a. The first cover 103A in the illustrated example has a hexagonal shape. The second cover 103B covers a portion of the circuit substrate 106 extending from the center toward the first sensor 104 or the second sensor 105. In the illustrated example, the second cover 103B has a rectangular shape. A plurality of second covers 103B are spaced apart from the peripheral edge of the first cover 103A and disposed radially along the radial direction of the base substrate 102.

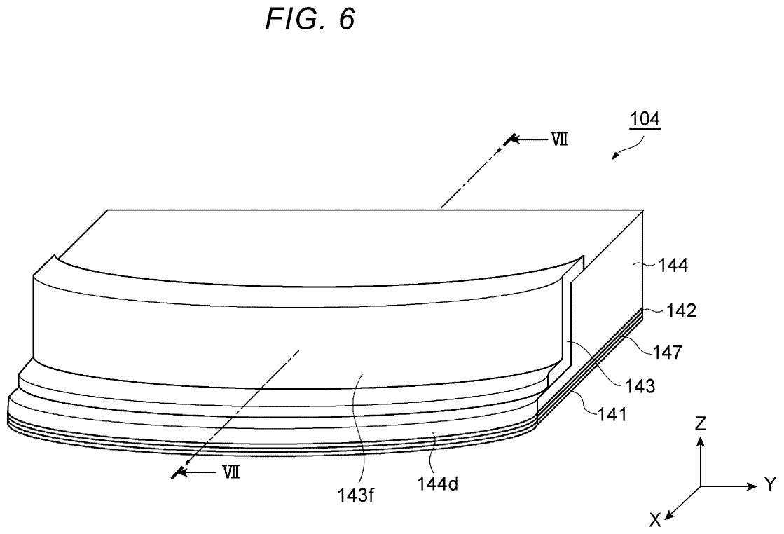

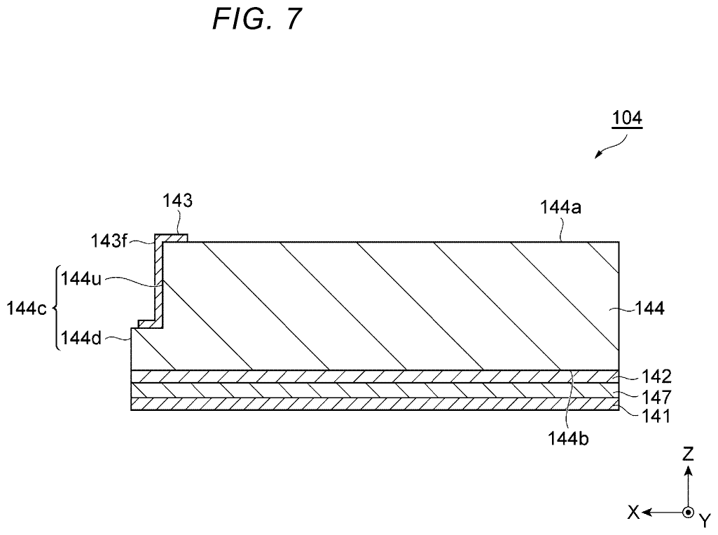

Hereinafter, the first sensor will be described in detail. FIG. 6 is a perspective view illustrating an example of the sensor. FIG. 7 is a cross-sectional view taken along a line VII-VII in FIG. 6. In an example, the first sensor 104 illustrated in FIGS. 6 and 7 is configured as a chip-shaped component. In the following description, an XYZ orthogonal coordinate system will be referred to as appropriate. The X direction indicates the forward direction of the first sensor 104, the Y direction indicates the width direction of the first sensor 104 in one direction orthogonal to the X direction, and the Z direction indicates the upward direction of the first sensor 104 in a direction orthogonal to the X direction and the Y direction.

The first sensor 104 includes an electrode 141, a guard electrode 142, a sensor electrode 143, a substrate portion 144, and an insulating region 147.

The substrate portion 144 is formed of, for example, borosilicate glass or quartz. The substrate portion 144 has an upper surface 144a, a lower surface 144b, and a front end surface 144c. The guard electrode 142 is provided below the lower surface 144b of the substrate portion 144 and extends in the X direction and the Y direction. The electrode 141 is provided below the guard electrode 142 with the insulating region 147 interposed therebetween, and extends in the X direction and the Y direction. The insulating region 147 is formed of, for example, SiO₂, SiN, Al₂O₃, or polyimides.

The front end surface 144c of the substrate portion 144 is formed in a stepped shape. A lower portion 144d of the front end surface 144c protrudes outward in a horizontal direction from an upper portion 144u of the front end surface 144c. The sensor electrode 143 extends along the upper portion 144u of the front end surface 144c. In one exemplary embodiment, the upper portion 144u and the lower portion 144d of the front end surface 144c are each curved having a predetermined curvature. That is, the upper portion 144u of the front end surface 144c has a constant curvature at any position of the upper portion 144u, and the curvature of the upper portion 144u is the reciprocal of the distance between a central axis AX100 of the measuring instrument 100 and the upper portion 144u of the front end surface 144c. The lower portion 144d of the front end surface 144c has a constant curvature at any position of the lower portion 144d, and the curvature of the lower portion 144d is the reciprocal of the distance between the central axis AX100 of the measuring instrument 100 and the lower portion 144d of the front end surface 144c.

The sensor electrode 143 is provided along the upper portion 144u of the front end surface 144c. In one exemplary embodiment, a front surface 143f of the sensor electrode 143 is also curved. That is, the front surface 143f of the sensor electrode 143 has a constant curvature at any position of the front surface 143f, and the curvature is the reciprocal of the distance between the central axis AX100 of the measuring instrument 100 and the front surface 143f.

In a case of using the first sensor 104 as the sensor of the measuring instrument 100, the electrode 141 is connected to the wiring 181, the guard electrode 142 is connected to the wiring 182, and the sensor electrode 143 is connected to the wiring 183 as described later.

In the first sensor 104, the sensor electrode 143 is shielded from below the first sensor 104 by the electrode 141 and the guard electrode 142. Therefore, according to the first sensor 104, it is possible to measure the capacitance with high directivity in a specific direction, that is, in a direction (X direction) in which the front surface 143f of the sensor electrode 143 faces.

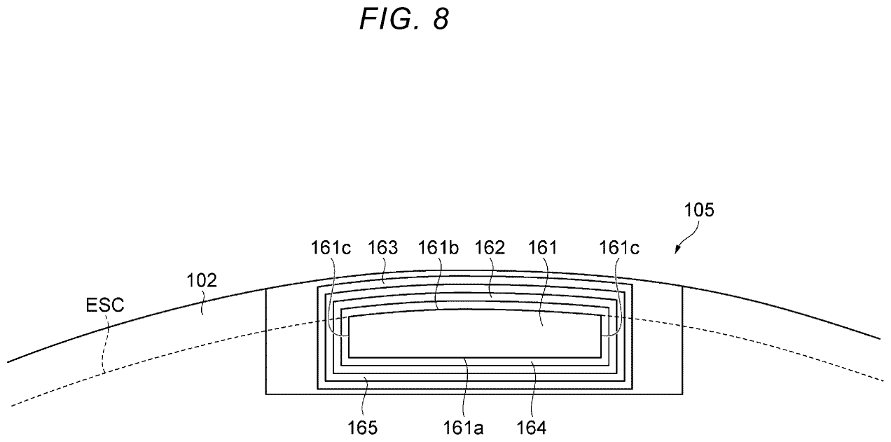

Hereinafter, the second sensor will be described. FIG. 8 is a partially enlarged view of FIG. 5, and illustrates one second sensor. In an example, the second sensor 105 is configured as a chip-shaped component and includes a sensor electrode 161. A part of an edge of the sensor electrode 161 has a circular arc shape. For example, the sensor electrode 161 has a planar shape defined by an inner edge 161a, an outer edge 161b, and a side edge 161c. As an example, the outer edge 161b has an arc shape having a radius around the central axis AX 100, and the side edge 161c and the inner edge 161a have a straight shape. The outer edges 161b on the outer side in the radial direction of the respective sensor electrodes 161 of the second sensors 105A to 105C extend on a common circle. A curvature of a part of the edge of the sensor electrode 161 coincides with a curvature of an edge of the electrostatic chuck ESC. In one exemplary embodiment, the curvature of the outer edge 161b forming the edge on the outer side in the radial direction of the sensor electrode 161 coincides with the curvature of the edge of the electrostatic chuck ESC. A center of curvature of the outer edge 161b, that is, a center of the circle on which the outer edge 161b extends, shares the central axis AX 100.

In one exemplary embodiment, the second sensor 105 further includes a guard electrode 162 that surrounds the sensor electrode 161. The guard electrode 162 has a frame shape and surrounds the entire periphery of the sensor electrode 161. The guard electrode 162 and the sensor electrode 161 are spaced apart from each other such that an electrically insulating region 164 is interposed therebetween. In one exemplary embodiment, the second sensor 105 further includes an electrode 163 that surrounds the guard electrode 162 at an outer side of the guard electrode 162. The electrode 163 has a frame shape and surrounds the entire periphery of the guard electrode 162. The guard electrode 162 and the electrode 163 are spaced apart from each other such that an electrically insulating region 165 is interposed therebetween.

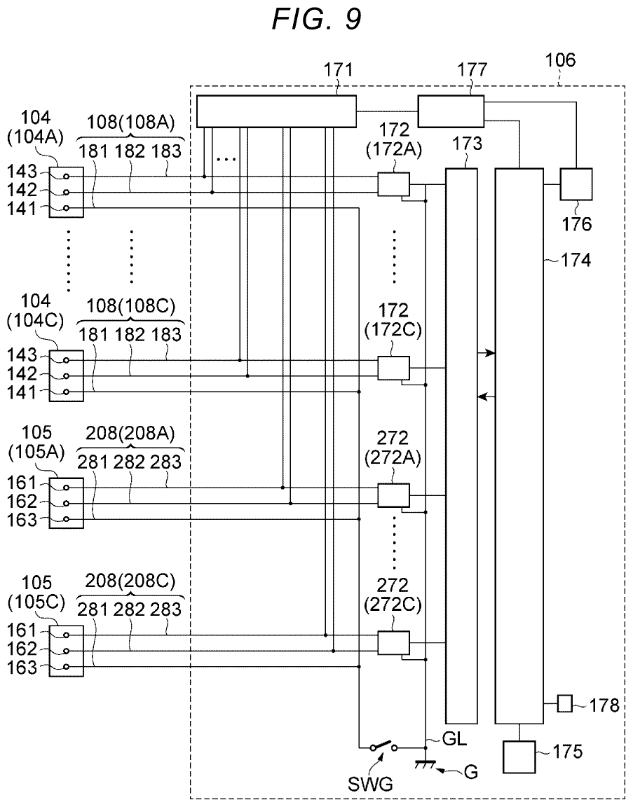

Hereinafter, a configuration of the circuit substrate 106 will be described. FIG. 9 is a view illustrating a configuration of a circuit substrate of the measuring instrument. The circuit substrate 106 includes a radio frequency oscillator 171, C/V conversion circuits 172A to 172C, C/V conversion circuits 272A to 272C, an A/D converter 173, a processor 174, a storage device 175, a communication device 176, and a power supply 177. In an example, a controller (arithmetic unit) is configured by the processor 174, the storage device 175, and the like.

Each of the first sensors 104A to 104C is connected to the circuit substrate 106 through a corresponding wiring group among the wiring groups 108A to 108C. Further, each of the first sensors 104A to 104C is connected to the corresponding C/V conversion circuit among the C/V conversion circuits 172A to 172C through several wirings included in the corresponding wiring group. Each of the second sensors 105A to 105C is connected to the circuit substrate 106 through a corresponding wiring group among the wiring groups 208A to 208C. Further, each of the second sensors 105A to 105C is connected to the corresponding C/V conversion circuit among the C/V conversion circuits 272A to 272C through several wirings included in the corresponding wiring group. Hereinafter, one first sensor 104 having the same configuration as each of the first sensors 104A to 104C, one wiring group 108 having the same configuration as each of the wiring groups 108A to 108C, and one C/V conversion circuit 172 having the same configuration as each of the C/V conversion circuits 172A to 172C will be described. Further, one second sensor 105 having the same configuration as each of the second sensors 105A to 105C, one wiring group 208 having the same configuration as each of the wiring groups 208A to 208C, and one C/V conversion circuit 272 having the same configuration as each of the C/V conversion circuits 272A to 272C will be described.

The wiring group 108 includes wirings 181 to 183. One end of the wiring 181 is connected to the electrode 141. The wiring 181 is connected to a ground potential line GL connected to the ground G of the circuit substrate 106. The wiring 181 may be connected to the ground potential line GL through a switch SWG. One end of the wiring 182 is connected to the guard electrode 142, and the other end of the wiring 182 is connected to the C/V conversion circuit 172. One end of the wiring 183 is connected to the sensor electrode 143, and the other end of the wiring 183 is connected to the C/V conversion circuit 172.

The wiring group 208 includes wirings 281 to 283. One end of the wiring 281 is connected to the electrode 163. The wiring 281 is connected to the ground potential line GL connected to the ground G of the circuit substrate 106. The wiring 281 may be connected to the ground potential line GL through the switch SWG. One end of the wiring 282 is connected to the guard electrode 162, and the other end of the wiring 282 is connected to the C/V conversion circuit 272. One end of the wiring 283 is connected to the sensor electrode 161, and the other end of the wiring 283 is connected to the C/V conversion circuit 272.

The radio frequency oscillator 171 is connected to the power supply 177 such as a battery, and configured to receive power from the power supply 177 to generate a radio frequency signal. The power supply 177 is also connected to the processor 174, the storage device 175, and the communication device 176. The radio frequency oscillator 171 has a plurality of output lines. The radio frequency oscillator 171 provides the generated radio frequency signal to the wirings 182 and 183, as well as the wirings 282 and 283, via the plurality of output lines. Accordingly, the radio frequency oscillator 171 is electrically connected to the guard electrode 142 and the sensor electrode 143 of the first sensor 104, and the radio frequency signal from the radio frequency oscillator 171 is provided to the guard electrode 142 and the sensor electrode 143. The radio frequency oscillator 171 is electrically connected to the sensor electrode 161 and the guard electrode 162 of the second sensor 105, and the radio frequency signal from the radio frequency oscillator 171 is provided to the sensor electrode 161 and the guard electrode 162.

The wiring 182 connected to the guard electrode 142 and the wiring 183 connected to the sensor electrode 143 are connected to the input of the C/V conversion circuit 172. That is, the guard electrode 142 and the sensor electrode 143 of the first sensor 104 are connected to the input of the C/V conversion circuit 172. Further, the sensor electrode 161 and the guard electrode 162 are connected to the input of the C/V conversion circuit 272. The C/V conversion circuit 172 and the C/V conversion circuit 272 are configured to generate a voltage signal having an amplitude according to a potential difference at their inputs, and output the voltage signal. The C/V conversion circuit 172 generates a voltage signal according to the capacitance formed by the corresponding first sensor 104. That is, as the capacitance of the sensor electrode connected to the C/V conversion circuit 172 increases, the magnitude in voltage of the voltage signal that is output from the C/V conversion circuit 172 increases. Similarly, as the capacitance of the sensor electrode connected to the C/V conversion circuit 272 increases, the magnitude in voltage of the voltage signal that is output from the C/V conversion circuit 272 increases.

The outputs of the C/V conversion circuit 172 and the C/V conversion circuit 272 are connected to the input of the A/D converter 173. Further, the A/D converter 173 is connected to the processor 174. The A/D converter 173 is controlled according to a control signal from the processor 174, converts an output signal (voltage signal) from the C/V conversion circuit 172 and an output signal (voltage signal) from the C/V conversion circuit 272 into digital values, and outputs the digital values to the processor 174 as detection values.

The storage device 175 is connected to the processor 174. The storage device 175 is a storage device such as a volatile memory, and stores measured data, for example. Further, another storage device 178 is connected to the processor 174. The storage device 178 is a storage device such as a nonvolatile memory, and stores, for example, a program that is read and executed by the processor 174.

The communication device 176 is a communication device based on any radio communication standard. For example, the communication device 176 is based on Bluetooth (registered trademark). The communication device 176 is configured to wirelessly transmit measured data stored in the storage device 175.

The processor 174 is configured to control each part of the measuring instrument 100 by executing the program described above. For example, the processor 174 controls the supply of the radio frequency signal from the radio frequency oscillator 171 to the guard electrode 142, the sensor electrode 143, the sensor electrode 161, and the guard electrode 162. Further, the processor 174 controls the supply of power from the power supply 177 to the storage device 175, the supply of power from the power supply 177 to the communication device 176, and the like. Further, the processor 174 executes the program described above to acquire measured values of the first sensor 104 and measured values of the second sensor 105 based on a detection value input from the A/D converter 173. In one embodiment, when the detection value output from the A/D converter 173 is set as X, the processor 174 acquires the measured value based on the detection value such that the measured value is proportional to (a· X+b). Here, a and b are constants that vary depending on a circuit state or the like. The processor 174 may have, for example, a predetermined arithmetic expression (function) such that the measured value is proportional to (a· X+b).

In the measuring instrument 100 described above, a plurality of sensor electrodes 143 and the guard electrode 142 face the inner edge of the edge ring ER in a state where the measuring instrument 100 is disposed in the region surrounded by the edge ring ER. A measured value generated based on the potential difference between the signal from the sensor electrode 143 and the signal from the guard electrode 142 indicates the capacitance that reflects the distance between each of the sensor electrodes 143 and the edge ring ER. The capacitance C is expressed by C=εS/d. ¿ is the permittivity of the medium between the front surface 143f of the sensor electrode 143 and the inner edge of the edge ring ER, S is the area of the front surface 143f of the sensor electrode 143, and d can be regarded as the distance between the front surface 143f of the sensor electrode 143 and the inner edge of the edge ring ER.

Therefore, according to the measuring instrument 100, measured data reflecting a relative positional relationship between the measuring instrument 100 mimicking the workpiece W and the edge ring ER is obtained. For example, as the distance between the front surface 143f of the sensor electrode 143 and the inner edge of the edge ring ER is larger, the measured values acquired by the measuring instrument 100 are smaller. Therefore, a misalignment amount of each sensor electrode 143 in each radial direction of the edge ring ER can be obtained based on the measured value indicating the capacitance of the sensor electrode 143 of each of the first sensors 104A to 104C. An error in the transport position of the measuring instrument 100 can be obtained based on the misalignment amount of the sensor electrode 143 of each of the first sensors 104A to 104C in each radial direction.

Further, in a state where the measuring instrument 100 is placed on the electrostatic chuck ESC, a plurality of sensor electrodes 161 and the guard electrode 162 face the electrostatic chuck ESC. As described above, the capacitance C is expressed by C=εS/d. ε is the permittivity of the medium between the sensor electrode 161 and the electrostatic chuck ESC, d is the distance between the sensor electrode 161 and the electrostatic chuck ESC, and S can be regarded as the area where the sensor electrode 161 and the electrostatic chuck ESC overlap each other in a plan view. The area S varies according to a relative positional relationship between the measuring instrument 100 and the electrostatic chuck ESC. Therefore, according to the measuring instrument 100, measured data reflecting the relative positional relationship between the measuring instrument 100 mimicking the workpiece W and the electrostatic chuck ESC is obtained.

In an example, when the measuring instrument 100 is transported to a predetermined transport position, that is, a position on the electrostatic chuck ESC where the center of the electrostatic chuck ESC and the center of the measuring instrument 100 coincide with each other, the outer edge 161b of the sensor electrode 161 and the edge of the electrostatic chuck ESC may coincide with each other. In this case, for example, when the transport position of the measuring instrument 100 is misaligned from the predetermined transport position, the area S becomes small when the sensor electrode 161 is misaligned outward in the radial direction with respect to the electrostatic chuck ESC. That is, the capacitance measured by the sensor electrode 161 is smaller than the capacitance measured when the measuring instrument 100 is transported to the predetermined transport position. Therefore, the misalignment amount of each sensor electrode 161 in each radial direction of the electrostatic chuck ESC can be obtained based on the measured values indicating the capacitance of the sensor electrodes 161 of each of the second sensors 105A to 105C. The error in the transport position of the measuring instrument 100 can be obtained based on the misalignment amount of the sensor electrode 161 of each of the second sensors 105A to 105C in each radial direction.

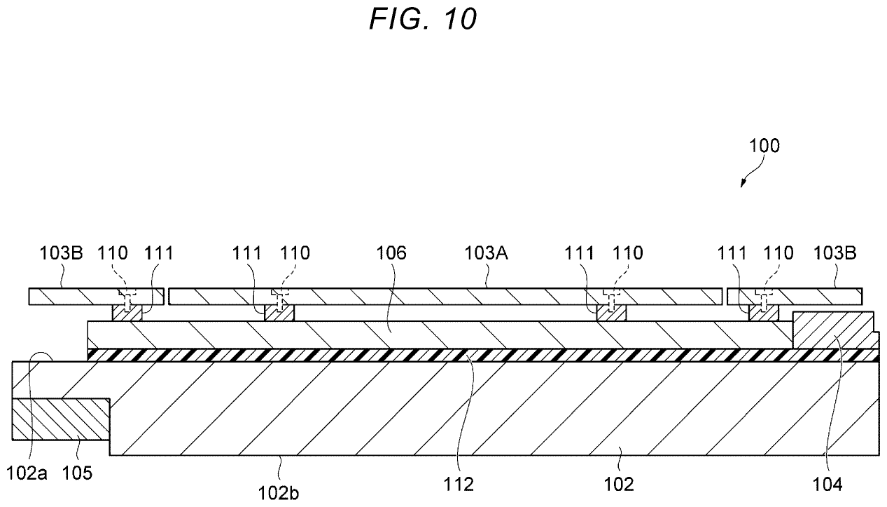

The measuring instrument 100 will be further described. FIG. 10 is a cross-sectional view taken along the line X-X in FIG. 4, and schematically illustrates a cross-sectional structure of the measuring instrument 100. As shown in FIG. 10, the measuring instrument 100 includes the base substrate 102, the first sensor 104 provided on the upper surface 102a of the base substrate 102, and the second sensor 105 provided on the lower surface 102b of the base substrate 102. Further, the measuring instrument 100 includes the circuit substrate 106 provided on the upper surface 102a of the base substrate 102, and the cover 103 provided to cover the circuit substrate 106.

As described above, in the measuring instrument 100 according to the exemplary embodiment, the base substrate 102, the circuit substrate 106, and the cover 103 are arranged to be stacked in the vertical direction. The base substrate 102, the circuit substrate 106, and the cover 103 have smaller expansion rate as the vertical position thereof increases from top to bottom. That is, the expansion rate of the base substrate 102 is smaller than the expansion rate of the circuit substrate 106, and the expansion rate of the circuit substrate 106 is smaller than the expansion rate of the cover 103.

In an example, the base substrate 102 may be made of a material such as monocrystalline silicon, carbon fiber reinforced plastic (CFRP), silicon carbide (SiC), or alumina. The circuit substrate 106 may be made of a material such as glass epoxy, polyimide (PI) resin, liquid crystal polymer (LCP), alumina, alumina zirconia, aluminum nitride, silicon nitride, or low temperature co-fired ceramic (LTCC). The glass epoxy may be Flame Retardant Type 4 (FR-4). The cover 103 may be made of a resin material, such as polyether ether ketone (PEEK) resin, polytetrafluoroethylene (PTFE) resin, polyphenylene sulfide (PPS) resin, and epoxy resin, but is not limited thereto. The cover 103 may be made of a metal material, such as stainless steel (SUS) or aluminum.

The circuit substrate 106 and the first sensor 104 are fixed to the upper surface 102a of the base substrate 102 by an elastic adhesive layer 112. That is, the elastic adhesive layer 112 is disposed between the base substrate 102, the circuit substrate 106, and the first sensor 104. The elastic adhesive layer 112 may be formed of, for example, an adhesive having rubber-like elasticity by curing. In an example, the elastic adhesive layer 112 may contain silicone as a main component.

The cover 103 may be fixed to the circuit substrate 106. In one exemplary embodiment, the cover 103 includes the first cover 103A and the second cover 103B. The first cover 103A and the second cover 103B are separately formed from each other, and are fixed to the circuit substrate 106 by different fastening members 110. For example, when the fastening member 110 is a bolt, the fastening member 110 that fixes the cover 103 may be fastened to a female screw member 111 (fastening member) fixed on the circuit substrate 106.

In the illustrated example, the first cover 103A is fixed to the circuit substrate 106 by a plurality of fastening members 110. Each of the plurality of second covers 103B is fixed to the circuit substrate 106 by one fastening member 110. In the example of FIG. 10, the position of the fastening member 110 that fixes each of the second covers 103B is biased to the edge portion of the second cover 103B, but the fastening member 110 may be disposed at the center of each of the second covers 103B. The center may be a center of gravity in a planar shape. The first cover 103A may be fixed to the circuit substrate 106 by one fastening member 110. Each of the plurality of second covers 103B may be fixed to the circuit substrate 106 by the plurality of fastening members 110.

For example, the cover 103 may be fixed to the base substrate 102. That is, the base substrate 102 may have a female screw member that penetrates the circuit substrate 106 and protrudes upward above the circuit substrate 106, and the fastening member 110 may fasten the cover 103 to the female screw member.

The height position of the lower surface of the second sensor 105 is offset from the height position of the lower surface 102b of the base substrate 102 toward the upper surface 102a of the base substrate 102. That is, the lower surface of the second sensor 105 is recessed toward the upper surface 102a from the height position of the lower surface 102b of the base substrate 102. For example, a notched portion for disposing the second sensor 105 may be formed at the peripheral edge of the lower surface 102b of the base substrate 102. In this case, the height of the notched portion is larger than the height of the second sensor 105.

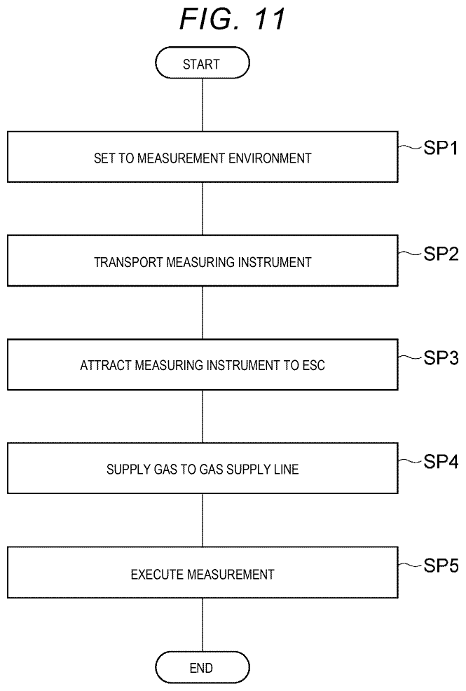

FIG. 11 is a flowchart illustrating a step in which a capacitance is measured by the measuring instrument 100. The operations in the flowchart are controlled by the processor 174 of the measuring instrument 100 or the controller MC of the processing system. When the measurement of the capacitance is performed, the measuring instrument 100 may be stored in any of the containers 4a to 4d.

First, the temperature environment inside the chamber of the plasma processing apparatus 10 is adjusted to be compatible with the measurement environment (step SP1). In an example, the environment inside the chamber may be adjusted based on a process treatment recipe used when a process treatment is executed. That is, the environment inside the chamber may be optionally set by a user according to the conditions of the assumed process treatment. For example, the temperature of the upper electrode 30 may be controlled to about 200° C. The temperature of the deposition shield 46 may be controlled to about 200° C. The temperature of the stage ST may be controlled to about 80° C. The gas pressure in the chamber may be about 0.1 m Torr to 500 m Torr.

Subsequently, the measuring instrument 100 is transported to a position on the placement region specified by the transport position data by the transport device TU2 (step SP2). In step SP2, the transport device TU1 transports the measuring instrument 100 to either the load-lock module LL1 or LL2 of the containers 4a to 4d. The transport device TU2 transports the measuring instrument 100 from the one of the load-lock modules to any of the process modules PM1 to PM6 based on the transport position data, and places the measuring instrument 100 on the placement region of the electrostatic chuck ESC. The transport position data is coordinate data determined in advance such that the position of the central axis AX100 of the measuring instrument 100 coincides with the central position of the edge ring ER. The transport position data may be coordinate data predetermined so that the position of the central axis AX100 of the measuring instrument 100 coincides with the central position of the electrostatic chuck ESC.

Subsequently, the measuring instrument 100 is attracted onto the electrostatic chuck ESC (step SP3). That is, the electrostatic chuck ESC attracts the measuring instrument 100 (the base substrate 102) by an electrostatic force such as a Coulomb force generated by the DC voltage from the DC power source 22.

Subsequently, a heat transfer gas such as a He gas is supplied from the gas supply line 28 provided in the plasma processing apparatus 10 between the upper surface of the electrostatic chuck ESC and the lower surface 102b of the measuring instrument 100 (step SP4).

Subsequently, a measurement is performed by the measuring instrument 100 (step SP5). In step SP5, the output signals (voltage signals) of the C/V conversion circuit 172 and the C/V conversion circuit 272 are converted to digital values by an A/D converter and output to the processor 174 as detection values. The detection value may be converted by the processor 174 into a measurement value representing capacitance. The acquired capacitance data can be stored in the storage device 175 for each sensor, in association with temperature data, detection values, and the like.

In one exemplary embodiment, the misalignment amount of the center of the measuring instrument 100 with respect to the central position of the edge ring ER can be derived based on the respective capacitances acquired by the first sensors 104A to 104C. Further, based on the respective capacitance acquired by the second sensors 105A to 105C, a misalignment amount of the center of the measuring instrument 100 with respect to the central position of the electrostatic chuck ESC can be derived. The misalignment amount may be used, for example, for calibration of transport position data used for transport by the transport device TU2. In an example, after the transport position data is calibrated based on the above-described operation flow, the process treatment of the workpiece W may be executed based on a process treatment recipe.

As described above, in one exemplary embodiment, the measuring instrument 100 is provided. The measuring instrument 100 includes a base substrate 102 having a disk shape. The measuring instrument 100 includes the plurality of first sensors 104 arranged along a peripheral edge of the base substrate 102. The plurality of first sensors 104 measure the capacitance between the plurality of first sensors 104 and the edge ring ER disposed beside the base substrate 102. The measuring instrument 100 includes the circuit substrate 106 fixed on the base substrate 102. The circuit substrate 106 includes an arithmetic unit that controls the plurality of first sensors 104. The measuring instrument 100 includes the cover 103 fixed to the circuit substrate 106 or the base substrate 102 to cover the top of the circuit substrate 106. The expansion rate of the base substrate 102 is smaller than the expansion rate of the circuit substrate 106. The expansion rate of the circuit substrate 106 is smaller than the expansion rate of the cover 103.

The measuring instrument 100 includes the first sensor 104 that measures the capacitance according to (i.e., based on) the distance between the measuring instrument 100 and the edge ring ER that is an object, and the second sensor 105 that measures the capacitance according to (i.e., based on) the distance between the second sensor 105 and the electrostatic chuck ESC (i.e., the object), and the facing area between the second sensor 105 and the electrostatic chuck ESC. The measuring instrument 100 can derive the transport position during the transport based on the capacitances acquired by the first sensor 104 and the second sensor 105. As a result, the transport data of the transport devices TU1 and TU2 can be calibrated. Each member configuring the chamber S may be deformed by thermal expansion due to temperature increase during plasma processing (process treatment). Therefore, it is required to execute the measurement with the measuring instrument 100 under the same temperature environment as the temperature environment in the process of plasma processing the workpiece W. However, when the measuring instrument 100 is exposed to a temperature environment of plasma processing, the measuring instrument 100 may be irregularly deformed by the influence of thermal expansion. In this case, the distance between the electrostatic capacitance sensor and the object may vary, making it impossible to accurately acquire capacitance that correctly reflects the distance.

In the above-described measuring instrument 100, the circuit substrate 106 is fixed on the disk-shaped base substrate 102, and the cover 103 that covers the circuit substrate 106 is fixed to the base substrate 102 or the circuit substrate 106. In the above-described measuring instrument 100, the base substrate 102, the circuit substrate 106, and the cover 103 are configured to be sequentially overlapped from the lower side to the upper side. The expansion rate of the base substrate 102 is the smallest, followed by the circuit substrate 106 and cover 103, in that order. In this configuration, when exposed to a high-temperature environment similar to that in which process treatment is performed, the deformation amount (expansion amount) of the cover 103 is the highest, followed by the circuit substrate 106 and base substrate 102, in that order. Therefore, the deformation amount of the measuring instrument 100 due to thermal expansion is controlled so that the peripheral edge bends downward so that the cover 103, which has a larger deformation amount, is pulled by the base substrate 102, which has a smaller deformation. In this case, the variation in the height position of the peripheral edge of the measuring instrument 100 is suppressed in a state where the measuring instrument 100 is placed at a predetermined position. That is, when comparing a high-temperature environment and a normal-temperature environment, the distance between the measuring instrument 100 and the edge ring ER disposed beside the measuring instrument 100 is unlikely to vary. The capacitance acquired by the first sensor 104 depends on the distance between the first sensor 104 and the edge ring ER. Therefore, it is possible to measure the capacitance with high accuracy even in a high-temperature environment.

In one exemplary embodiment, the base substrate 102 may be made of any one of materials of monocrystalline silicon, carbon fiber reinforced plastic, silicon carbide, and alumina. The circuit substrate 106 may be made of any one of materials of a glass epoxy material and a polyimide resin material. The cover 103 may be made of any one of materials of polyether ether ketone resin, polytetrafluoroethylene resin, polyphenylene sulfide resin, and epoxy resin. According to this configuration, the measuring instrument 100 having the characteristic of the expansion rate described above can be manufactured.

In one exemplary embodiment, the cover 103 may include the first cover 103A and the second cover 103B which are separately formed from each other. The first cover 103A and the second cover 103B may be fixed to the circuit substrate 106 by different fastening members 110. In this configuration, the deformation amount of the cover 103 can be reduced compared to the case where the cover 103 is integrated. That is, it is possible to reduce the influence of the deformation of the cover 103 on the circuit substrate 106 and the base substrate 102.

In one exemplary embodiment, the second cover 103B may extend along the radial direction of the base substrate 102 spaced apart from the peripheral edge of the first cover 103A. In this configuration, since the deformation of the measuring instrument 100 is along the radial direction, for example, the distortion along the circumferential direction can be reduced.

In one exemplary embodiment, the first cover 103A may be disposed at the center of the base substrate 102. The plurality of second covers 103B may be arranged radially around the first cover 103A. In this configuration, deviation of deformation in the circumferential direction is suppressed. In particular, the plurality of second covers 103B extend from the first cover 103A toward the first sensor 104 or the second sensor 105. Therefore, deviation of deformation between the positions at which the first sensor 104 and the second sensor 105 are disposed in the circumferential direction is suppressed.

In one exemplary embodiment, the circuit substrate 106 may be fixed on the base substrate 102 by the elastic adhesive layer 112. In this configuration, the elastic adhesive layer 112 can mitigate the effect of the amount of change in the circuit substrate 106 on the base substrate 102. That is, when the elastic adhesive layer 112 follows the deformation of the circuit substrate 106, the external force that the circuit substrate 106 exerts on the base substrate 102 can be absorbed. Therefore, the base substrate 102 can be gently bent. Further, the separation of the circuit substrate 106 from the base substrate 102 is suppressed.

In one exemplary embodiment, the measuring instrument 100 may include the plurality of second sensors 105 arranged along a peripheral edge of the base substrate 102. The plurality of second sensors 105 measure capacitance between plurality of second sensors 105 and the electrostatic chuck ESC disposed below the base substrate 102. The height positions of the lower surfaces of the plurality of second sensors 105 may be offset from the height position of the lower surface 102b of the base substrate 102 toward the upper surface 102a of the base substrate 102. For example, when the second sensor 105 is offset below the lower surface 102b of the base substrate 102, the base substrate 102 is supported by the second sensor 105. In this case, if the measuring instrument 100 is exposed to a high-temperature environment on the electrostatic chuck ESC, the base substrate 102 may deform toward the electrostatic chuck ESC. In the configuration described above, the base substrate 102 is not supported by the plurality of second sensors 105. Therefore, deformation of the base substrate 102 is suppressed.

In one exemplary embodiment, a measuring method is provided for acquiring, by the measuring instrument 100, a measurement value representing capacitance in the chamber S of a processing system for executing process treatment. The measuring method includes controlling a temperature environment in the chamber S. The measuring method includes transporting the measuring instrument 100 by the transport devices TU1 and TU2 onto the electrostatic chuck ESC in the chamber S in which a temperature environment is controlled. The measuring method includes attracting the measuring instrument 100 transported onto the electrostatic chuck ESC to the electrostatic chuck ESC. The measuring method includes acquiring a measurement value representing the capacitance between the measuring instrument and the edge ring ER that surrounds the measuring instrument 100 by the measuring instrument 100 attracted to the electrostatic chuck ESC.

In this method, the base substrate 102 is pressed against the placing surface of the electrostatic chuck ESC as the measuring instrument 100 is attracted to the electrostatic chuck ESC, thereby suppressing distortion of the measuring instrument 100. Further, in this method, the temperature of the measuring instrument 100 can be controlled based on the temperature control of the electrostatic chuck ESC by supplying a He gas between the electrostatic chuck ESC and the measuring instrument 100. Due to such temperature control, the deformation of the measuring instrument 100 may be further suppressed.

While various exemplary embodiments have been described above, various omissions, substitutions, and changes may be made without being limited to the exemplary embodiments described above.

Although the measuring instrument 100 including the three first sensors 104 and the three second sensors 105 have been illustrated, the number of electrostatic capacitance sensors installed in the measuring instrument 100 may be increased or decreased. Further, only either the first sensor 104 or the second sensor 105 may be mounted.

Although an example in which the first cover 103A and the second cover 103B are spaced apart from each other when viewed from the vertical direction has been described, the first cover 103A and the second cover 103B may have regions that partially overlap each other when viewed from the vertical direction. In this case, the region between the first cover 103A and the second cover 103B may be covered with the overlapping portion of the first cover 103A and the second cover 103B.

In the illustrated examples, the first cover 103A is fixed to the circuit substrate or the base substrate by a plurality of fastening members 110, but the first cover 103A may be fixed to the circuit substrate or the base substrate by one fastening member. In this case, the fastening member may be fixed to the central position of the first cover 103A. Further, when one cover is fixed by a plurality of fastening members, as in the first cover 103A of the illustrated example, the distance between the fastening members may be a distance shorter than half the length of the longest side of the cover.

From the foregoing, it will be appreciated that various embodiments of the present disclosure have been described herein for purposes of illustration, and that various modifications may be made without departing from the scope and spirit of the present disclosure. Therefore, the various embodiments disclosed herein are not intended to be limiting, with the true scope and spirit being indicated by the following claims.

Hereinafter, one or more embodiments in the present disclosure will be described in [E] to [E8].

### [E1]

A measuring instrument including
a base substrate having a disk shape,
a plurality of first sensors arranged along a peripheral edge of the base substrate and configured to measure capacitance between the plurality of first sensors and a first object disposed beside the base substrate,
a circuit substrate fixed on the base substrate and including an arithmetic unit that controls the plurality of first sensors, and
a cover fixed to the circuit substrate or the base substrate to cover a top of the circuit substrate, in which
an expansion rate of the base substrate is smaller than an expansion rate of the circuit substrate, and
the expansion rate of the circuit substrate is smaller than an expansion rate of the cover.

### [E2]

In the measuring instrument according to E1, the base substrate is made of any one of materials of monocrystalline silicon, carbon fiber reinforced plastic, silicon carbide, and alumina, the circuit substrate is made of any one of materials of glass epoxy and polyimide resin, and the cover is made of any one of materials of polyether ether ketone resin, polytetrafluoroethylene resin, polyphenylene sulfide resin, and epoxy resin.

### [E3]

In the measuring instrument according to E1 or E2, the cover includes a first cover and a second cover which are separately formed from each other, and the first cover and the second cover are fixed to the circuit substrate or the base substrate by different fastening members.

### [E4]

In the measuring instrument according to E3, the second cover is spaced apart from a peripheral edge of the first cover and extends along a radial direction of the base substrate.

### [E5]

In the measuring instrument according to E3 or E4, a plurality of the second covers are provided, the first cover is disposed at a center of the base substrate, and the plurality of second covers are radially disposed around the first cover.

### [E6]

In the measuring instrument according to any one of E1 to E5, the circuit substrate is fixed on the base substrate by an elastic adhesive.

### [E7]

The measuring instrument according to any one of E1 to E6, further including
a plurality of second sensors arranged along a peripheral edge of the base substrate and configured to measure capacitance between the plurality of second sensors and a second object disposed below the base substrate, in which
height positions of lower surfaces of the plurality of second sensors are offset from a height position of a lower surface of the base substrate toward an upper surface of the base substrate.

### [E8]

A measuring method for acquiring, by a measuring instrument, a measurement value representing capacitance in a chamber of a processing system for executing process treatment, in which
the processing system includes
   a process module having a chamber main body that provides the chamber, and
   a transport device that transports the measuring instrument into the chamber, the process module includes at least
   an electrostatic chuck provided in the chamber and on which the measuring instrument is placed, and
   an edge ring disposed around a peripheral edge of the electrostatic chuck, and the measuring instrument includes
   a base substrate having a disk shape,
   a plurality of sensors arranged along a peripheral edge of the base substrate to measure capacitance,
   a circuit substrate fixed on the base substrate and including an arithmetic unit that controls the plurality of sensors, and
   a cover fixed to the circuit substrate or the base substrate to cover a top of the circuit substrate,
   an expansion rate of the base substrate is smaller than an expansion rate of the circuit substrate,
   the expansion rate of the circuit substrate is smaller than an expansion rate of the cover, the method including
      controlling a temperature environment in the chamber,
      transporting the measuring instrument by the transport device onto the electrostatic chuck in the chamber in which the temperature environment is controlled,
      attracting the measuring instrument transported on the electrostatic chuck to electrostatic chuck, and
      acquiring a measurement value representing capacitance between the measuring instrument and the edge ring that surrounds the measuring instrument by the measuring instrument attracted to the electrostatic chuck.

1. A measuring instrument comprising:
a base substrate having a disk shape;
a plurality of first sensors arranged along a peripheral edge of the base substrate and configured to measure capacitance between the plurality of first sensors and a first object disposed beside the base substrate;
a circuit substrate fixed on the base substrate and including a controller having a processor and a memory with a computer readable program stored therein, the controller being configured to control the plurality of first sensors; and
a cover fixed to the circuit substrate or the base substrate to cover a top of the circuit substrate, wherein
an expansion rate of the base substrate is smaller than an expansion rate of the circuit substrate, and
the expansion rate of the circuit substrate is smaller than an expansion rate of the cover.

2. The measuring instrument according to claim 1, wherein
the base substrate is made from one of monocrystalline silicon, carbon fiber reinforced plastic, silicon carbide, and alumina,
the circuit substrate is made from one of glass epoxy and polyimide resin, and
the cover is made from one of polyether ether ketone resin, polytetrafluoroethylene resin, polyphenylene sulfide resin, and epoxy resin.

3. The measuring instrument according to claim 1, wherein
the cover includes a first cover and a second cover, the first cover and the second cover are separately formed from each other, and
the first cover and the second cover are fixed to the circuit substrate or the base substrate by different fastening members.

4. The measuring instrument according to claim 3, wherein
the second cover is spaced apart from a peripheral edge of the first cover and extends along a radial direction of the base substrate.

5. The measuring instrument according to claim 4, wherein
a plurality of the second covers are provided,
the first cover is disposed at a center of the base substrate, and
the plurality of second covers are radially disposed around the first cover.

6. The measuring instrument according to claim 1, wherein
the circuit substrate is fixed on the base substrate by an elastic adhesive.

7. The measuring instrument according to claim 1, further comprising:
a plurality of second sensors arranged along a peripheral edge of the base substrate and configured to measure capacitance between the plurality of second sensors and a second object disposed below the base substrate, wherein
height positions of lower surfaces of the plurality of second sensors are offset from a height position of a lower surface of the base substrate toward an upper surface of the base substrate.

8. The measuring instrument according to claim 1, wherein each of the plurality of first sensors comprises:
a sensor electrode;
a guard electrode disposed below the sensor electrode; and
an electrode disposed below the guard electrode, the electrode being connected to a ground potential, and
the sensor electrode is configured to measure capacitance with high directivity toward the first object.

9. The measuring instrument according to claim 7, wherein each of the plurality of second sensors comprises:
a sensor electrode having an outer edge with a curvature configured to match a curvature of an edge of an electrostatic chuck;
a guard electrode surrounding the sensor electrode; and
an electrode surrounding the guard electrode, the electrode being connected to a ground potential.

10. A measuring instrument comprising:
a base substrate having a disk shape and a diameter configured to match a diameter of a semiconductor wafer;
a plurality of first sensors arranged at equal intervals along a peripheral edge of the base substrate, each first sensor configured to measure capacitance between the first sensor and an edge ring disposed beside the base substrate;
a plurality of second sensors arranged at equal intervals along the peripheral edge of the base substrate, each second sensor configured to measure capacitance between the second sensor and an electrostatic chuck disposed below the base substrate;
a circuit substrate fixed on the base substrate, the circuit substrate including a controller having a processor and a memory with a computer readable program stored therein, the controller being configured to control the plurality of first sensors and the plurality of second sensors;
a cover fixed to the circuit substrate, the cover comprising a first cover disposed at a center of the base substrate and a plurality of second covers radially arranged around the first cover; and
an elastic adhesive layer disposed between the circuit substrate and the base substrate, wherein
a coefficient of thermal expansion of the base substrate is smaller than a coefficient of thermal expansion of the circuit substrate, and
the coefficient of thermal expansion of the circuit substrate is smaller than a coefficient of thermal expansion of the cover.

11. The measuring instrument according to claim 10, wherein the plurality of first sensors and the plurality of second sensors are alternately arranged at approximately 60-degree intervals in a circumferential direction of the base substrate.

12. The measuring instrument according to claim 10, wherein
height positions of lower surfaces of the plurality of second sensors are offset from a height position of a lower surface of the base substrate toward an upper surface of the base substrate.

13. A measuring method for acquiring, by a measuring instrument, a measurement value representing capacitance in a chamber of a processing system for executing process treatment, wherein
the processing system includes:
a process module having a chamber main body that provides the chamber, and
a transport device that transports the measuring instrument into the chamber, the process module includes at least:
an electrostatic chuck provided in the chamber and on which the measuring instrument is placed, and
an edge ring disposed around a peripheral edge of the electrostatic chuck, and the measuring instrument includes:
a base substrate having a disk shape,
a plurality of sensors arranged along a peripheral edge of the base substrate to measure capacitance,
a circuit substrate fixed on the base substrate and including a controller having a processor and a memory with a computer readable program stored therein, the controller being configured to control the plurality of sensors, and
a cover fixed to the circuit substrate or the base substrate to cover a top of the circuit substrate,
an expansion rate of the base substrate is smaller than an expansion rate of the circuit substrate,
the expansion rate of the circuit substrate is smaller than an expansion rate of the cover,
the method comprising:
controlling a temperature environment in the chamber;
transporting the measuring instrument by the transport device onto the electrostatic chuck in the chamber in which the temperature environment is controlled;
attracting the measuring instrument transported on the electrostatic chuck to the electrostatic chuck; and
acquiring a measurement value representing capacitance between the measuring instrument and the edge ring that surrounds the measuring instrument by the measuring instrument attracted to the electrostatic chuck.

14. The measuring method according to claim 12, further comprising:
supplying a heat transfer gas between an upper surface of the electrostatic chuck and a lower surface of the measuring instrument after attracting the measuring instrument to the electrostatic chuck, to control a temperature of the measuring instrument.

15. The measuring method according to claim 12, further comprising:
deriving a misalignment amount of a center of the measuring instrument relative to a central position of the edge ring based on capacitance measurement values acquired by the plurality of sensors; and
calibrating transport position data for the transport device based on the misalignment amount.

16. The measuring method according to claim 12, further comprising:
converting, by a plurality of capacitance-to-voltage (C/V) conversion circuits in the measuring instrument, capacitances measured by the plurality of sensors into voltage signals;
converting, by an analog-to-digital (A/D) converter in the measuring instrument, the voltage signals into digital values; and
processing, by the controller, the digital values to obtain the measurement value representing capacitance.

17. The measuring method according to claim 12, wherein acquiring the measurement value comprises:
applying a radio frequency signal to sensor electrodes and guard electrodes of the plurality of sensors using a radio frequency oscillator in the measuring instrument; and
generating a voltage signal based on a potential difference between the sensor electrodes and the guard electrodes, the voltage signal corresponding to the capacitance between the measuring instrument and the edge ring.

18. The measuring method according to claim 12, wherein the plurality of sensors includes:
a plurality of first sensors; and
a plurality of second sensors, wherein
height positions of lower surfaces of the plurality of second sensors are offset from a height position of a lower surface of the base substrate toward an upper surface of the base substrate.

19. The measuring method according to claim 18, wherein the plurality of first sensors and the plurality of second sensors are alternately arranged at approximately 60-degree intervals in a circumferential direction of the base substrate.

20. The measuring method according to claim 12, wherein
the cover includes a first cover and a second cover,
the first cover and the second cover are separately formed from each other,
the first cover and the second cover are fixed to the circuit substrate by different fastening members,
the first cover has a hexagonal shape in a plan view, and
the second cover has a rectangular shape extending radially from the first cover.
